(19) United States
(12) Patent Application Publication
(10) Pub. No.: US 2026/0018430 A1
(43) Pub. Date: Jan. 15, 2026

(54) SUBSTRATE PROCESSING APPARATUS

(71) Applicant: Samsung Display Co., LTD., Yongin-si (KR)

(72) Inventor: JONGPILL PARK, Yongin-si (KR)

(21) Appl. No.: 19/097,600

(22) Filed: Apr. 1, 2025

(30) Foreign Application Priority Data
Jul. 10, 2024 (KR) 10-2024-0091105

(51) Int. Cl. H01L 21/67; H10K 77/10; H10K 102/00

(52) U.S. Cl. CPC H01L 21/67017; H01L 21/67253; H10K 77/111; H10K 2102/311

(57) ABSTRACT

A substrate processing apparatus includes a chamber in which a substrate is disposed, an external air supply pipe connected to a first side of the chamber and extending into the chamber, a gas supply pipe disposed inside the external air supply pipe, a mesh filter disposed inside the external air supply pipe and between an end of the gas supply pipe and an end of the external air supply pipe, and a plurality of first discharge pipes connected to a second side of the chamber which is opposite to the first side and extending into the chamber.

This application claims priority to Korean Patent Application No. 10-2024-0091105, filed on Jul. 10, 2024, and all the benefits accruing therefrom under 35 U.S.C. § 119, the content of which in its entirety is herein incorporated by reference.

### BACKGROUND

### 1. Field

The disclosure herein relates to a substrate processing apparatus.

### 2. Description of the Related Art

Electronic apparatuses such as a smart phone, a digital camera, a laptop computer, a navigation unit, and a smart television, which provide images to a user, include a display device for displaying images. Such a display device generates images and provides the images to a user via a display screen.

Recently, various types of display devices are being developed with development of the technology for the display device. For example, a variety of flexible display devices, which are deformable into curved shapes, foldable, or rollable, are being developed. The flexible display devices having diversely deformable shapes are easy to carry and improve user's convenience.

The flexible display device includes a flexible substrate and a plurality of pixels arranged on the flexible substrate. The flexible substrate is manufactured by coating a plastic material on a glass substrate and curing the plastic material. This process is defined as a substrate processing process.

### SUMMARY

During the curing process of plastic materials, fumes are generated, and thus it is desired to develop a technology for easily removing the fumes.

The disclosure provides a substrate processing apparatus capable of preventing a substrate from being contaminated by easily removing fumes generated during a substrate processing process.

An embodiment of the inventive concept provides a substrate processing apparatus including: a chamber in which a substrate is disposed; an external air supply pipe connected to a first side of the chamber and extending into the chamber; a gas supply pipe disposed inside the external air supply pipe; a mesh filter disposed inside the external air supply pipe and between an end of the gas supply pipe and an end of the external air supply pipe; and a plurality of first discharge pipes connected to a second side of the chamber which is opposite to the first side and extending into the chamber.

In an embodiment of the inventive concept, a substrate processing apparatus includes: a chamber in which a substrate is disposed; an external air supply pipe connected to a first side of the chamber and extending into the chamber; a gas supply pipe disposed inside the external air supply pipe; a plurality of first discharge pipes connected to a second side of the chamber which is opposite to the first side and extending into the chamber; and a plurality of discharge valves, outside the chamber, respectively connected to the first discharge pipes, wherein the discharge valves control open ratios of passages inside the first discharge pipes, and the open ratios of the passages of the first discharge pipes gradually increase toward an upper portion.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of a substrate processing apparatus according to the inventive concept;

FIGS. 2 to 5 are views illustrating display devices including substrates manufactured by the substrate processing apparatus illustrated in FIG. 1;

FIG. 6 is a view briefly illustrating a method for manufacturing a flexible substrate;

FIG. 7 is a view illustrating a configuration of a pixel disposed on the flexible substrate illustrated in FIG. 6;

FIGS. 8 and 9 are cross-sectional views taken along line I-I′ illustrated in FIG. 1, and for schematically describing substrate processing processes;

FIGS. 10 and 11 are cross-sectional views taken along line II-II′ illustrated in FIG. 1;

FIG. 12 is a view separately illustrating first and second gas supply pipes illustrated in FIGS. 10 and 11;

FIG. 13 is a perspective view of one mesh filter illustrated in FIG. 10;

FIG. 14 is a view for describing a configuration in which the mesh filter illustrated in FIG. 13 is coupled to a corresponding first external air supply pipe;

FIG. 15 is a view illustrating an embodiment of an arrangement position of a mesh filter according to the inventive concept;

FIG. 16 is a side view of a discharge part illustrated in FIG. 1;

FIG. 17 is a cross-sectional view taken along line III-III′ illustrated in FIG. 1;

FIG. 18 is a view illustrating the common discharge pipe, the fume trap, the second pressure measurement portion, and the common discharge valve which are illustrated in FIG. 1;

FIG. 19 is a view illustrating a barrier film of the common discharge valve disposed inside the common discharge pipe illustrated in FIG. 18;

FIG. 20 is an exploded perspective view of first and second support parts and rollers disposed below one substrate illustrated in FIG. 8; and

FIG. 21 is a view describing an operation of first and second support bars entering into and exiting from a chamber via rollers.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents.

The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the drawing figures. It will be understood that the terms have a relative concept and are described on the basis of the orientation depicted in the drawing figures.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Hereinafter, embodiments of the inventive concept will be described with reference to the drawings.

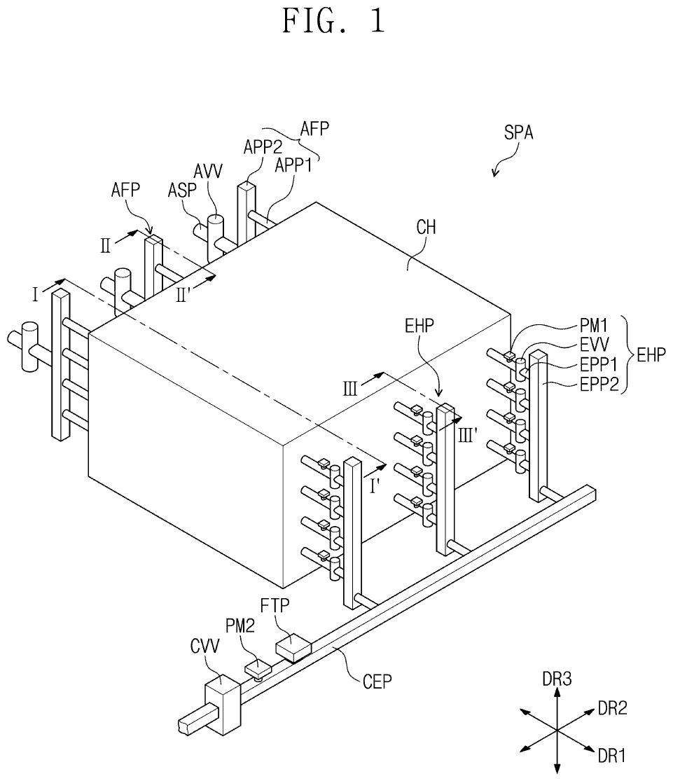

FIG. 1 is a perspective view of an embodiment of a substrate processing apparatus according to the inventive concept.

Referring to FIG. 1, a substrate processing apparatus SPA may include a process chamber CH (hereinafter, also referred to as a chamber), a plurality of air flow supply parts AFP, and a plurality of discharge parts EHP.

The chamber CH may have a quadrangular shape, e.g., rectangular parallelepiped shape, but a shape of the chamber CH is not limited thereto. The chamber CH may extend longer in a second direction DR2 perpendicular to a first direction DR1 than in the first direction DR1. Additionally, the chamber CH may extend longer in the first direction DR1 than a third direction DR3 perpendicular to a plane defined by the first and second directions DR1 and DR2.

Hereinafter, in this specification, the wording “in a plan view” may be defined as a state when viewed in the third direction DR3.

The air flow supply parts AFP may extend in the third direction DR3 and be arranged in the second direction DR2. The air flow supply parts AFP may be connected to one side (also referred to as a first side) of opposite sides, of the chamber CH, opposed to each other in the first direction DR1.

The discharge parts EHP may extend in the third direction DR3 and be arranged in the second direction DR2. The discharge parts EHP may be connected to a remaining (the other) side (also referred to as a second side) of opposite sides, of the chamber CH, opposed to each other in the first direction DR1.

The substrate processing apparatus SPA may include a plurality of external air supply pipes ASP connected to the air flow supply parts AFP and a plurality of external air valves AVV. Additionally, the substrate processing apparatus SPA may include a common discharge pipe CEP connected to the discharge parts EHP, a fume trap FTP, a second pressure measurement portion PM2, and a common discharge valve CVV.

The air flow supply parts AFP each have the substantially same configuration, and thus a configuration of one air flow supply part AFP will be described below. Also, the external air supply pipes ASP may each have the substantially same configuration, and the external air valves AVV may each have the substantially same configuration. Accordingly, configurations of the external air supply pipe ASP and the external air valve AVV which are connected to one air flow supply part AFP will be described.

The air flow supply part AFP may include a plurality of first external air supply pipes APP1 and a second external air supply pipe APP2. The first external air supply pipes APP1 may extend in the first direction DR1, and be arranged in the third direction DR3. In an embodiment, the first external air supply pipes APP1 may have a cylindrical shape extending in the first direction DR1. One side of opposite sides, of each first external air supply pipe APP1, opposed to each other in the first direction DR1 may be connected to the one side of the chamber CH.

The second external air supply pipe APP2 may extend in the third direction DR3. In an embodiment, the second external air supply pipe APP2 may have a square pillar shape extending in the third direction DR3, for example. The second external air supply pipe APP2 may be connected to a remaining (the other) side of opposite sides, of each first external air supply pipe APP1, opposed to each other in the first direction DR1. A passage defined inside the second external air supply pipe APP2 may be defined to be continuous with passages defined inside the first external air supply pipes APP1.

The external air supply pipe ASP may extend in the first direction DR1 and be connected to the second external air supply pipe APP2. A passage defined inside the external air supply pipe ASP may be defined to be continuous with the passage defined inside the second external air supply pipe APP2.

The external air valve AVV may be connected to the external air supply pipe ASP. The external air valve AVV may function as a valve, and close or open the external air supply pipe ASP. In an embodiment, the external air valve AVV may close or open the passage defined inside the external air supply pipe ASP, for example. The valve may be implemented in various forms, and thus a description of a detailed configuration of the valve is omitted.

The discharge parts EHP each have the substantially same configuration, and thus a configuration of one discharge part EHP will be described below.

The discharge part EHP may include a plurality of first discharge pipes EPP1, a second discharge pipe EPP2, a plurality of discharge valves EVV, and a plurality of first pressure measurement portions PM1.

The first discharge pipes EPP1 may extend in the first direction DR1, and be arranged in the third direction DR3. In an embodiment, the first discharge pipes EPP1 may each have a cylindrical shape extending in the first direction DR1, for example. One side of opposite sides, of each first discharge pipe EPP1, opposed to each other in the first direction DR1 may be connected to the remaining (the other) side of the chamber CH opposite to the one side of the chamber CH.

The second discharge pipe EPP2 may extend in the third direction DR3. In an embodiment, the second discharge pipe EPP2 may have a square pillar shape extending in the third direction DR3, for example. The second discharge pipe EPP2 may be connected to a remaining (the other) side of opposite sides, of each first discharge pipe EPP1, opposed to each other in the first direction DR1. A passage defined inside the second discharge pipe EPP2 may be defined to be continuous with passages defined inside the first discharge pipes EPP1.

The discharge valves EVV may be respectively connected to the first discharge pipes EPP1 outside the chamber CH. The discharge valves EVV may be next (adjacent) to the second discharge pipe EPP2. The discharge valves EVV may respectively control open ratios of the passages inside the first discharge pipes EPP1. In an embodiment, the extent to which the passages defined inside the first discharge pipes EPP1 are open may be controlled by rotating barrier films of the discharge valves EVV, for example. This configuration will be described below in detail.

The first pressure measurement portions PM1 may be respectively connected to the first discharge pipes EPP1 outside the chamber CH. The first pressure measurement portions PM1 may be next (adjacent) to the chamber CH. The first pressure measurement portions PM1 may be disposed between the chamber CH and the discharge valves EVV.

The first pressure measurement portions PM1 may respectively measure pressures in the first discharge pipes EPP1. In an embodiment, the first pressure measurement portions PM1 may measure a pressure of an air flow via a passage defined inside each of the first discharge pipes EPP1, for example. In an embodiment, the first pressure measurement portions PM1 may each include a differential pressure gauge, for example.

The common discharge pipe CEP may extend in the second direction DR2. The second discharge pipes EPP2 of the discharge parts EHP may be connected to the common discharge pipe CEP. A passage defined inside the common discharge pipe CEP may be defined to be continuous with passages defined inside the second discharge pipes EPP2.

The fume trap FTP, the second pressure measurement portion PM2, and the common discharge valve CVV may be connected to the common discharge pipe CEP. The fume trap FTP and the second pressure measurement portion PM2 may be disposed more adjacent to the second discharge pipe EPP2 than the common discharge valve CVV. The fume trap FTP may be disposed more adjacent to the second discharge pipe EPP2 than the second pressure measurement portion PM2. Accordingly, the second pressure measurement portion PM2 may be disposed between the fume trap FTP and the common discharge valve CVV.

The functions of the external air valve AVV, the external air supply pipe ASP, the air flow supply parts AFP, the discharge parts EHP, the fume trap FTP, the second pressure measurement portion PM2, and the common discharge valve CVV will be described below in detail with reference to the drawings.

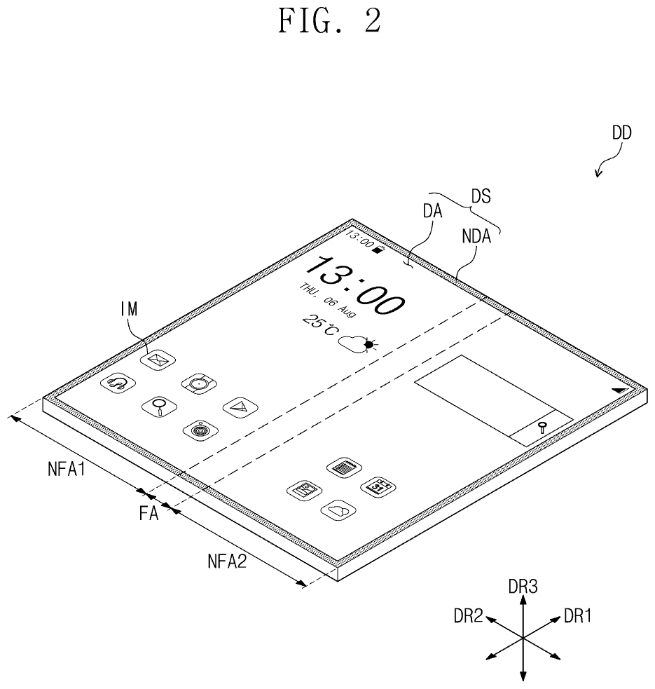

FIGS. 2 to 5 are views illustrating display devices including substrates manufactured by the substrate processing apparatus illustrated in FIG. 1.

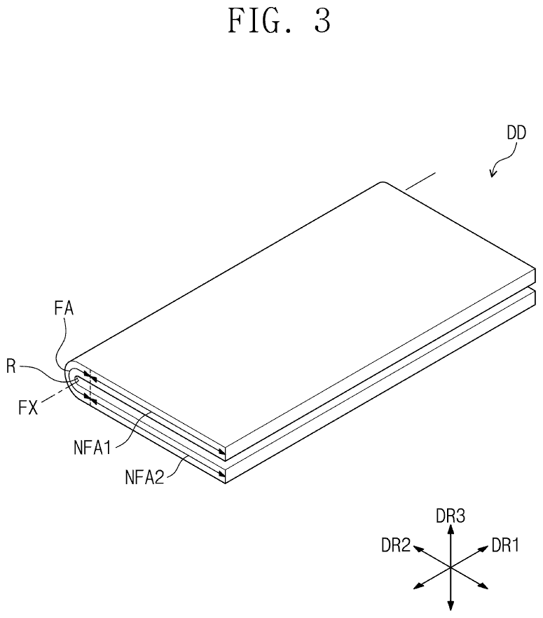

Referring to FIGS. 2 and 3, a display device DD in an embodiment of the inventive concept may have a quadrangular shape, e.g., rectangular shape which has long sides extending in the first direction DR1 and short sides extending in the second direction DR2 crossing the first direction DR1. The display device DD may be a flexible display device.

The display device DD may include a folding part FA and a plurality of non-folding parts NFA1 and NFA2 next (adjacent) to the folding part FA. The non-folding parts NFA1 and NFA2 may include a first non-folding part NFA1 and a second non-folding part NFA2. The folding part FA may be disposed between the first non-folding part NFA1 and the second non-folding part NFA2. The first non-folding part NFA1, the folding part FA, and the second non-folding part NFA2 may be arranged in the second direction DR2.

One folding part FA and two non-folding parts NFA1 and NFA2 are illustrated, but the number of the folding part FA and the number of the non-folding parts NFA1 and NFA2 are not limited thereto. In an embodiment, the display device DD may include more than two non-folding parts and a plurality of folding parts disposed with the non-folding parts therebetween, for example.

An upper surface of the display device DD may be defined as a display surface DS, and the display surface DS may have a flat surface defined by the first direction DR1 and the second direction DR2. Images IM generated by the display device DD may be provided to users through the display surface DS.

The display surface DS may include a display region DA and a non-display region NDA around the display region DA. The display region DA may display images, and the non-display region NDA may not display images. The non-display region NDA may surround the display region DA and define a border of the display device DD printed in a predetermined color.

The display device DD may be a folding-type (foldable) display device DD which is folded or unfolded. In an embodiment, the display device DD may be folded such that the folding part FA is bent with respect to a folding axis FX parallel to the first direction DR1, for example. The folding part FA may be folded so as to have a curvature radius R.

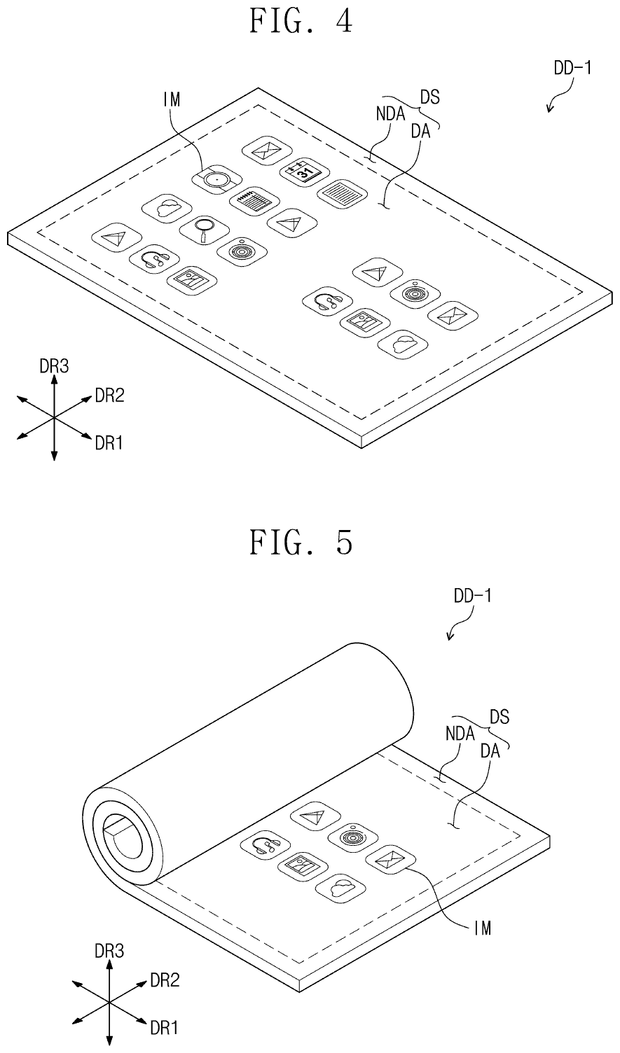

Referring to FIGS. 4 and 5, a display device DD-1 may have a quadrangular shape, e.g., rectangular shape which has long sides extending in the first direction DR1 and short sides extending in the second direction DR2. A display surface DS which provides images IM to users may include a display region DA and a non-display region NDA surrounding the display region DA, like the display device DD illustrated in FIG. 2.

The display device DD-1 may be a flexible display device. The display device DD-1 may be rolled like a scroll. The display device DD-1 may be rolled in the first direction DR1. The display device DD-1 may be rolled from one side of the display device DD-1. The display device DD-1 may be rolled such that the display surface DS faces the inside. However, the display device DD-1 is not limited thereto, and may also be rolled toward the outside of the display surface DS.

The above-described flexible display devices DD and DD-1 may include flexible substrates, and the flexible substrates may be manufactured by the substrate processing apparatus SPA illustrated in FIG. 1.

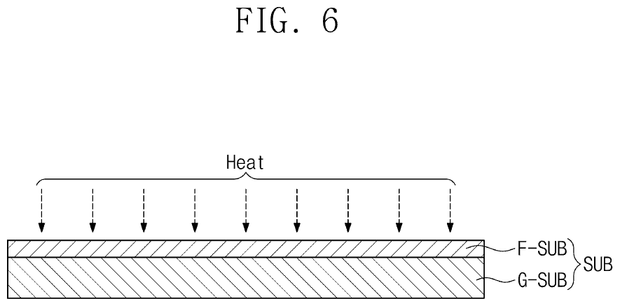

FIG. 6 is a view briefly illustrating a method for manufacturing a flexible substrate.

Referring to FIG. 6, a substrate SUB may include a glass substrate G-SUB and a flexible substrate F-SUB. During a substrate processing process, the glass substrate G-SUB may be prepared, and a flexible plastic material may be coated on the glass substrate G-SUB. The flexible plastic material coated on the glass substrate G-SUB may be defined as the flexible substrate F-SUB.

In order to cure the flexible plastic material, a curing process may be performed on the flexible substrate F-SUB. In an embodiment, the flexible substrate F-SUB may include polyimide, for example.

The curing process of the flexible substrate F-SUB is performed, and then the glass substrate G-SUB may be removed. Thereafter, elements of the display devices DD and DD-1 may be disposed on the cured flexible substrate F-SUB.

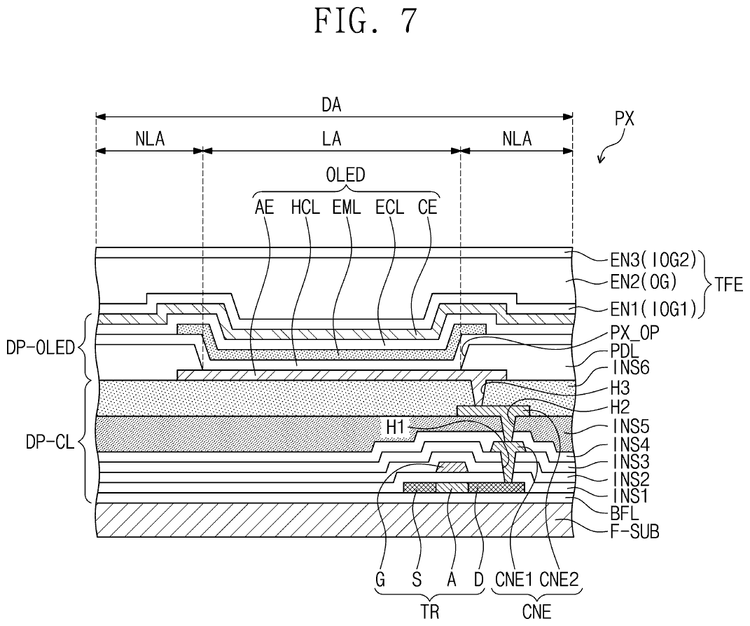

FIG. 7 is a view illustrating a configuration of a pixel disposed on the flexible substrate illustrated in FIG. 6.

Although not illustrated, the above-described display devices DD and DD-1 may include a plurality of pixels PX.

Referring to FIG. 7, the pixel PX may include a transistor TR and a light-emitting element OLED. The light-emitting element OLED may include a first electrode AE (or an anode), a second electrode CE (or a cathode), a hole control layer HCL, an electron control layer ECL, and a light-emitting layer EML.

The transistor TR and the light-emitting element OLED may be disposed on the flexible substrate F-SUB. One transistor TR is illustrated, but substantially, the pixel PX may include a plurality of transistors and at least one capacitor for driving the light-emitting element OLED.

A display region DA may include a light-emitting region LA corresponding to each of the pixels PX and a non-light-emitting region NLA around the light-emitting region LA. The light-emitting element OLED may be disposed in the light-emitting region LA.

A buffer layer BFL may be disposed on the flexible substrate F-SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly-doped region and a lightly-doped region. The highly-doped region may have conductivity higher than that of the lightly-doped region, and substantially serve as a source electrode and a drain electrode of the transistor TR. The lightly-doped region may substantially correspond to an active (or a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 for connecting the transistor TR and the light-emitting element OLED. The first connection electrode CNE1 may be disposed on the third insulating layer INS3 and connected to the drain D via a first contact hole H1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole H2 defined in the fourth and fifth insulating layers INS4 and INS5.

A sixth insulating layer INS6 may be disposed on the second connection electrode CNE2. The layers ranging from the buffer layer BFL to the sixth insulating layer INS6 may be defined as a circuit element layer DP-CL. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 via a third contact hole H3 defined in the sixth insulating layer INS6. A pixel-defining film PDL, in which an opening PX_OP for exposing a predetermined portion of the first electrode AE is defined, may be disposed on the first electrode AE and the sixth insulating layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having one color of red, green, or blue.

The electron control layer ECL may be disposed on the light-emitting layer EML and the hole control layer HCL. The electron control layer ECL may include an electron transport layer and an electron injection layer. The hole control layer HCL and the electron control layer ECL may be commonly disposed over the light-emitting region LA and the non-light-emitting region NLA.

The second electrode CE may be disposed on the electron control layer ECL. The second electrode CE may be disposed in the pixels PX in common. The layer on which the light-emitting element OLED is disposed may be defined as a display element layer DP-OLED.

A thin-film encapsulation layer TFE may be disposed on the second electrode CE to cover the pixels PX. The thin-film encapsulation layer TFE may include a first encapsulation layer EN1 disposed on the second electrode CE and a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and protect the pixels PX against moisture/oxygen. The second encapsulation layer EN2 may include an organic insulating layer and protect the pixels PX against foreign substances such as dust particles.

A first voltage may be applied to the first electrode AE via the transistor TR, and a second voltage having a level lower than that of the first voltage may be applied to the second electrode CE. Holes and electrons injected into the light-emitting layer EML are combined to form excitons, and the excitons transition to a ground state, so that the light-emitting element OLED may emit light.

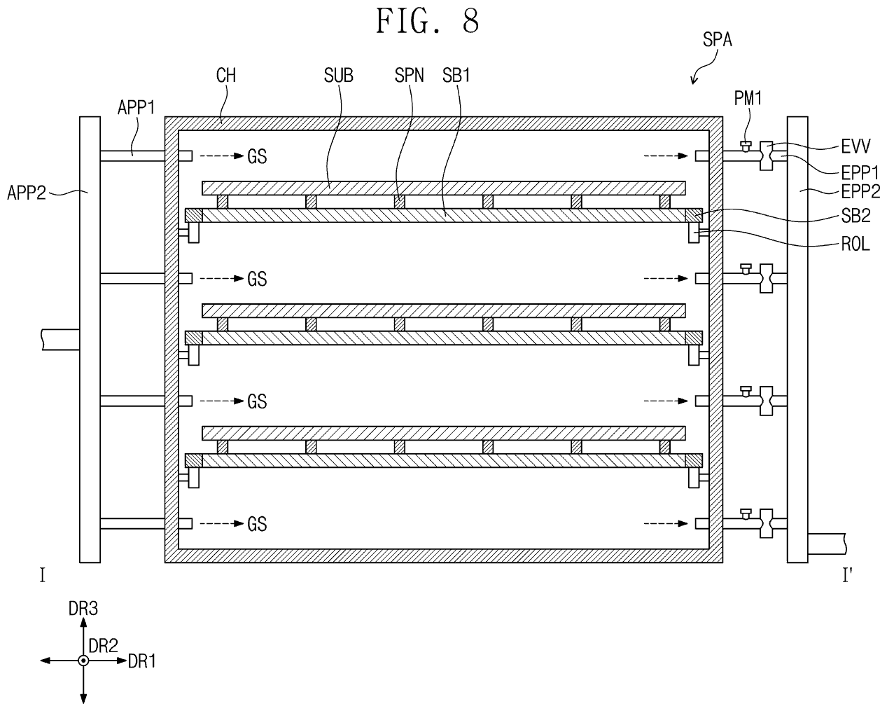

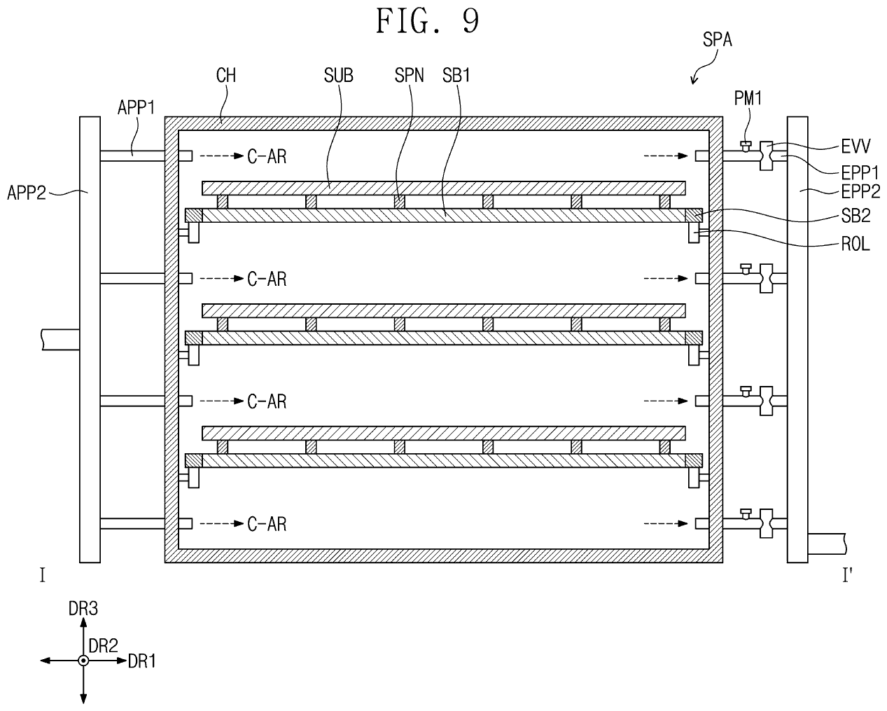

FIGS. 8 and 9 are cross-sectional views taken along line I-I′ illustrated in FIG. 1, and for schematically describing substrate processing processes.

Referring to FIG. 8, a substrate processing apparatus SPA may include a plurality of support bars SB1 and SB2, a plurality of support pins SPN, and a plurality of rollers ROL. The support bars SB1 and SB2, the support pins SPN, and the rollers ROL may be disposed inside a chamber CH.

The support bars SB1 and SB2 may include a plurality of first support bars SB1 and a plurality of second support bars SB2. The first support bars SB1 may extend in the first direction DR1. The second support bars SB2 may extend in the second direction DR2, and this configuration will be illustrated below in detail with reference to FIG. 19.

The second support bars SB2 may be spaced apart from each other in the first direction DR1, and be disposed next (adjacent) to inner side surfaces, of the chamber CH, facing each other in the first direction DR1. The first support bars SB1 may be disposed between the second support bars SB2. The support pins SPN may be disposed on the first support bars SB1, and extend in the third direction DR3.

The first support bars SB1 and the second support bars SB2 may be connected to each other. The support pins SPN may be connected to the first support bars SB1.

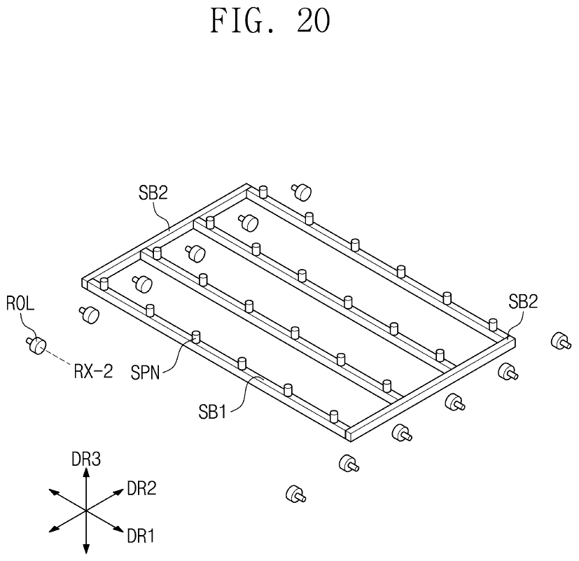

The rollers ROL may be disposed next (adjacent) to the inner side surfaces, of the chamber CH, facing each other in the first direction DR1. The rollers ROL may be connected to the inner side surfaces of the chamber CH. The second support bars SB2 may be disposed on the rollers ROL. The second support bars SB2 may move along the rotating rollers ROL. This configuration will be described below in detail with reference to FIG. 20.

A plurality of substrates SUB may be disposed inside the chamber CH. The substrates SUB may be disposed on the support pins SPN. The substrates SUB may be supported by the first and second support bars SB1 and SB2, and the support pins SPN.

The first and second support bars SB1 and SB2 may each include a heating wire. Since heat generated from the first and second support bars SB1 and SB2 is applied to the substrates SUB during the process of processing the substrate SUB, a curing process may be performed on the flexible substrate F-SUB. In an embodiment, heat of about 400 degrees Celsius to about 500 degrees Celsius may be applied to the substrates SUB, for example.

Although not illustrated, additionally, heating wires may be disposed at various positions inside the chamber CH (e.g., an inner side surface of the chamber CH), and heat generated from the heating wires may be applied to the substrates SUB disposed inside the chamber CH.

Referring to FIGS. 1 and 8, the first external air supply pipes APP1 may be connected to one side (also referred to as a first side) of the chamber CH and extend into the chamber CH. Accordingly, ends of the first external air supply pipes APP1 may be disposed inside the chamber CH.

The first discharge pipes EPP1 may be connected to a remaining (the other side) of the chamber CH opposite to the one side of the chamber CH and extend into the chamber CH. Accordingly, ends of the first discharge pipes EPP1 may be disposed inside the chamber CH.

When heat is applied to the substrates SUB and a curing process is performed on the substrates SUB, fumes may be generated on the flexible substrate F-SUB. The fumes may include contaminant particles.

An air flow may be formed inside the chamber CH in order to remove the fumes. In an embodiment, a gas GS may be injected into the chamber CH via the first external air supply pipes APP1, for example. In an embodiment, the gas GS may include nitrogen gas, for example.

The gas GS supplied into the chamber CH may be discharged via the first discharge pipes EPP1. The fumes may be discharged via the first discharge pipes EPP1 due to an air flow generated from the flow of the gas GS.

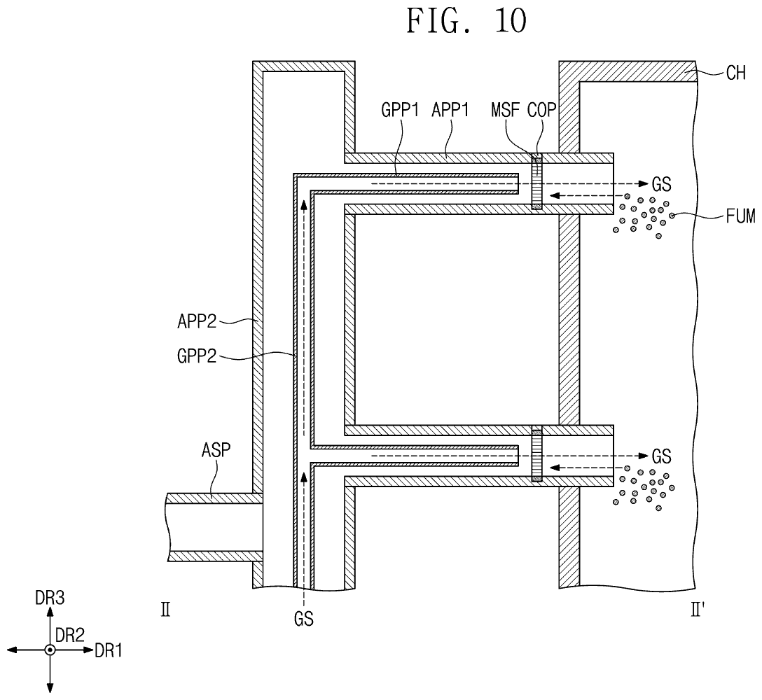

The gas GS may be substantially injected into the chamber CH via gas supply pipes separately disposed inside the first external air supply pipes APP1. This process may be defined as a gas injection process. A configuration of the gas supply pipes will be described below in detail with reference to FIGS. 10 to 12.

Referring to FIG. 9, after the curing process is performed, external air C-AR (air from the outside) may be injected into the chamber CH via the first external air supply pipes APP1 in order to cool the substrate SUB. This process may be defined as an external air injection process. The external air C-AR supplied into the chamber CH may be discharged via the first discharge pipes EPP1. The substrate SUB may be cooled to be at a room temperature by the external air C-AR. This process may be defined as a substrate cooling process.

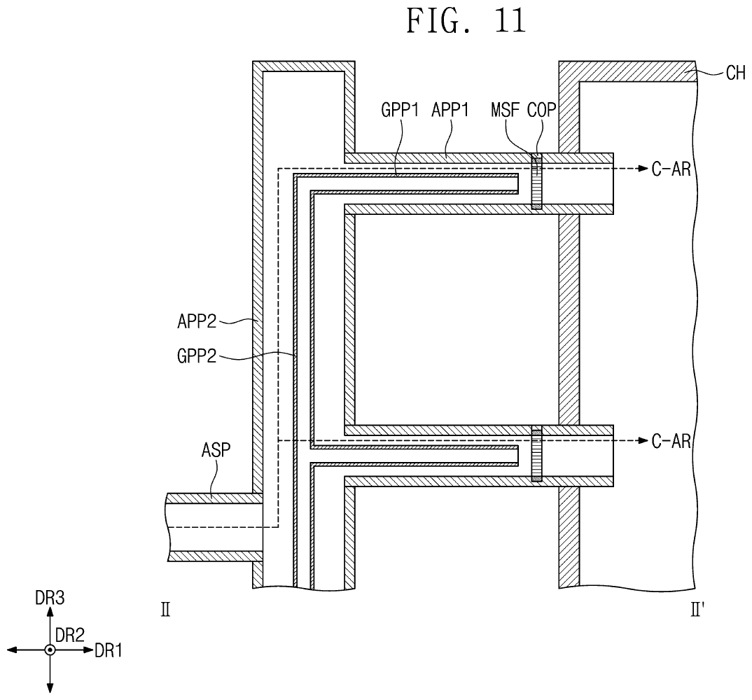

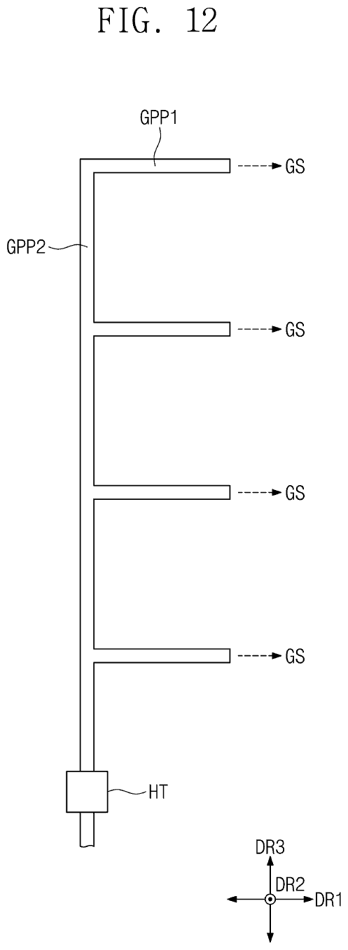

FIGS. 10 and 11 are cross-sectional views taken along line II-II′ illustrated in FIG. 1. FIG. 12 is a view separately illustrating the first and second gas supply pipes illustrated in FIGS. 10 and 11.

FIG. 10 may correspond to a view of the gas injection process illustrated in FIG. 8, and FIG. 11 may correspond to a view of the external air injection process illustrated in FIG. 9. In an embodiment, FIGS. 10 and 11 are enlarged views illustrating the first and second external air supply pipes APP1 and APP2, for example. Since FIGS. 10 and 11 are enlarged views of the first external air supply pipes APP1, all the first external air supply pipes APP1 are not illustrated, and for example, two first external air supply pipes APP1 disposed in an upper part are illustrated in FIGS. 10 and 11.

For convenience of description, in FIGS. 10 and 11, the substrates SUB, the rollers ROL, and the first and second support bars SB1 and SB2, which are disposed inside the chamber CH, are omitted. In an embodiment, FIG. 12 illustrates not cross sections of first and second gas supply pipes GPP1 and GPP2 but side surfaces of the first and second gas supply pipes GPP1 and GPP2 when viewed from the second direction DR2, for example.

Referring to FIGS. 1, 8 and 10, the substrate processing apparatus SPA may include the plurality of first gas supply pipes GPP1 disposed inside the first external air supply pipes APP1, and the second gas supply pipe GPP2 disposed inside the second external air supply pipe APP2.

The first gas supply pipes GPP1 may extend in the first direction DR1. The second gas supply pipe GPP2 may be connected to the first gas supply pipes GPP1 and extend in the third direction DR3. A passage defined inside the second gas supply pipe GPP2 may be defined to be continuous with passages defined inside the first gas supply pipes GPP1.

Although not illustrated, fixing portions which connect the first and second gas supply pipes GPP1 and GPP2 to inner side surfaces of the first and second external air supply pipes APP1 and APP2 may be disposed inside the first and second external air supply pipes APP1 and APP2.

The substrate processing apparatus SPA may include a plurality of mesh filters MSF respectively disposed inside the first external air supply pipes APP1. The mesh filters MSF may be disposed next (adjacent) to the respective ends of the first external air supply pipes APP1. The mesh filters MSF may be disposed inside the first external air supply pipes APP1, and cover parts COP may cover the mesh filters MSF. The mesh filters MSF may be closed by the cover parts COP from the outside.

The mesh filters MSF may be disposed between the ends of the first gas supply pipes GPP1 and the ends of the first external air supply pipes APP1. The ends of the first gas supply pipes GPP1 may be next (adjacent) to the mesh filters MSF. In an embodiment, the ends of the first gas supply pipes GPP1 and the mesh filters MSF may be disposed outside the chamber CH, for example.

A gas GS may be supplied to the second gas supply pipe GPP2. The gas GS may be supplied to the first gas supply pipes GPP1 via the second gas supply pipe GPP2. The gas GS may be injected into the chamber CH via the first gas supply pipes GPP1. The gas GS may pass through the mesh filters MSF, and then be injected into the chamber CH via the first external air supply pipes APP1.

When the gas GS is injected into the chamber CH, the above-described external air supply pipe ASP may be closed by the external air valve AVV. In an embodiment, a passage inside the external air supply pipe ASP may be closed by the external air valve AVV, for example. Accordingly, external air C-AR, which may flow into via the external air supply pipe ASP, is blocked, and thus may not be supplied to the first and second external air supply pipes APP1 and APP2.

Referring to FIGS. 10 and 12, a heater HT may be connected to a lower part of the second gas supply pipe GPP2. The heater HT heats the gas GS, and the heated gas GS may be supplied to the second gas supply pipe GPP2. The heated gas GS may be supplied to the first gas supply pipes GPP1 via the second gas supply pipe GPP2. The heated gas GS may be supplied to the chamber CH via the first gas supply pipes GPP1.

In a case in which the gas GS is not heated, a greater amount of the gas GS may move toward a lower portion inside the chamber CH when the gas GS with a relatively low temperature is injected into the chamber CH via the first gas supply pipes GPP1. That is, a great amount of the gas GS may move toward the lower portion inside the chamber CH, and a relatively small amount of the gas GS may be provided toward an upper portion inside the chamber CH. In this case, an air flow at the lower portion of the chamber CH may become stronger, and an air flow at the upper portion of the chamber CH may become weaker. Due to this difference in the air flows, vortex may be formed inside the chamber CH.

As described above, during a curing process of a substrate SUB, fumes FUM may be generated on the flexible substrate F-SUB. Due to the vortex, the fumes FUM may not be appropriately discharged via the first discharge pipes EPP1 and remain inside the chamber CH. The fumes FUM remaining inside the chamber CH may be adhered to an inner side surface of the chamber CH and dropped onto the substrates SUB during the substrate cooling process by the above-described external air C-AR, which results in contaminating the substrates SUB.

When the gas GS heated by the heater HT is supplied to the chamber CH, an amount of the gas GS provided toward the upper portion inside the chamber CH may increase, and an amount of the gas GS moving toward the lower portion inside the chamber CH may decrease than when the unheated gas GS is supplied to the chamber CH. Therefore, when the heated gas GS is supplied to the chamber CH, the relatively more uniform gas GS may be provided at the upper portion and the lower portion of the chamber CH than when the unheated gas GS is supplied to the chamber CH.

The fumes FUM generated during the curing process may be supplied into the first external air supply pipes APP1. In an embodiment of the inventive concept, the fumes FUM may be blocked (or filtered) by the mesh filters MSF next (adjacent) to the ends of the first external air supply pipes APP1. Accordingly, the fumes FUM may not be supplied into the first external air supply pipes APP1 disposed further inward than the mesh filters MSF.

When the mesh filters MSF are not used, the fumes FUM may be supplied into the first external air supply pipes APP1 to be adhered to inner side surfaces of the first external air supply pipes APP1. Therefore, the first external air supply pipes APP1 may be contaminated. Additionally, when the external air C-AR is supplied to the first external air supply pipes APP1, the fumes FUM adhered to the inner side surfaces of the first external air supply pipes APP1 re-flow into the chamber CH by the external air C-AR, and thus may contaminate the substrates SUB.

In an embodiment of the inventive concept, the fumes FUM supplied into the first external air supply pipes APP1 are blocked by the mesh filters MSF, and thus contamination of the first external air supply pipes APP1 and the substrates SUB may be prevented.

Referring to FIGS. 1, 9, and 11, after the curing process is performed, the supply of the gas GS is stopped, and the external air C-AR may be supplied to the first and second external air supply pipes APP1 and APP2. As illustrated above, the external air supply pipe ASP may be opened by the external air valve AVV, and the external air C-AR may flow into via the external air supply pipe ASP. The external air C-AR may be supplied to the first external air supply pipes APP1 via the second external air supply pipe APP2. The external air C-AR may be supplied into the chamber CH via the first external air supply pipes APP1.

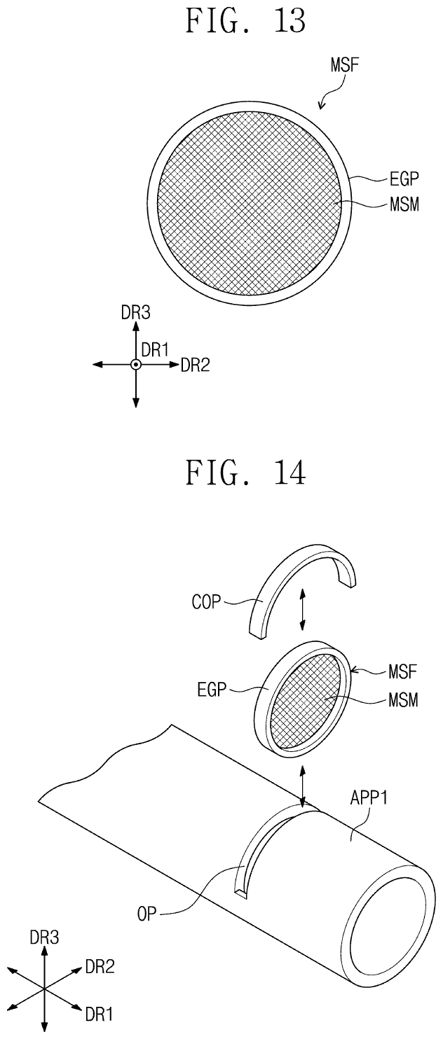

FIG. 13 is a perspective view of one mesh filter illustrated in FIG. 10. FIG. 14 is a view for describing a configuration in which the mesh filter illustrated in FIG. 13 is coupled to a corresponding first external air supply pipe.

Referring to FIGS. 10, 13, and 14, the mesh filter MSF may include a border portion EGP in a form of a ring, and a mesh net MSM disposed inside the border portion EGP. The mesh net MSM may have a mesh-like shape. In an embodiment, the mesh filter MSF may include or consist of stainless steel, for example.

When particles of the fumes FUM are continuously adsorbed onto the mesh filter MSF which filters the fumes FUM, the lifespan of the mesh filter MSF expires, and thus replacement of the mesh filter MSF may be desired. The mesh filter MSF may be detachably coupled to the first external air supply pipe APP1 through an opening OP defined in the first external air supply pipe APP1.

The mesh filter MSF may be inserted into the first external air supply pipe APP1 through the opening OP, and a cover part COP may cover the mesh filter MSF through the opening OP. When the life span of the mesh filter MSF expires, the cover part COP may be removed from the first external air supply pipe APP1, and the mesh filter MSF may be removed through the opening OP. Thereafter, a new mesh filter MSF may be coupled to the first external air supply pipe APP1.

The first external air supply pipe APP1 may include a transparent material. In an embodiment, the first external air supply pipe APP1 may include or consist of quartz, for example. Since the first external air supply pipe APP1 is transparent, it is possible to easily check whether the mesh filter MSF is in a contaminated condition. Therefore, whether to replace the mesh filter MSF may be more easily determined.

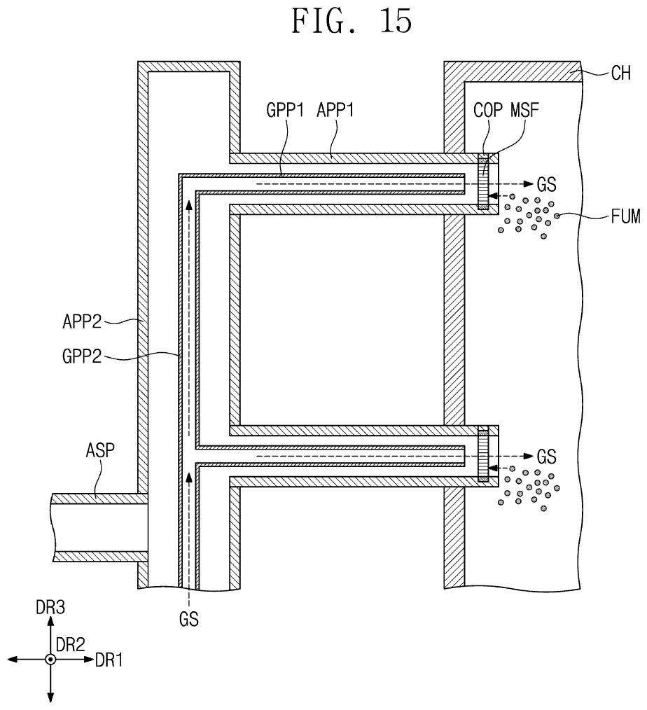

FIG. 15 is a view illustrating an embodiment of an arrangement position of a mesh filter according to the inventive concept.

For example, FIG. 15 illustrates a cross section corresponding to that of FIG. 10, for example, and hereinafter, the description of components illustrated in FIG. 15 will be mainly focused on components different from those illustrated in FIG. 10.

Referring to FIG. 15, positions of the mesh filters MSF may be variously set. In an embodiment, the ends of the first gas supply pipes GPP1 and the mesh filters MSF may be disposed inside the chamber CH, for example.

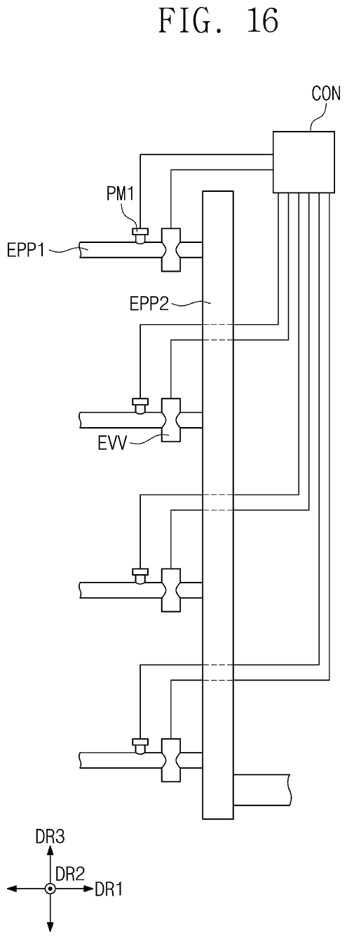

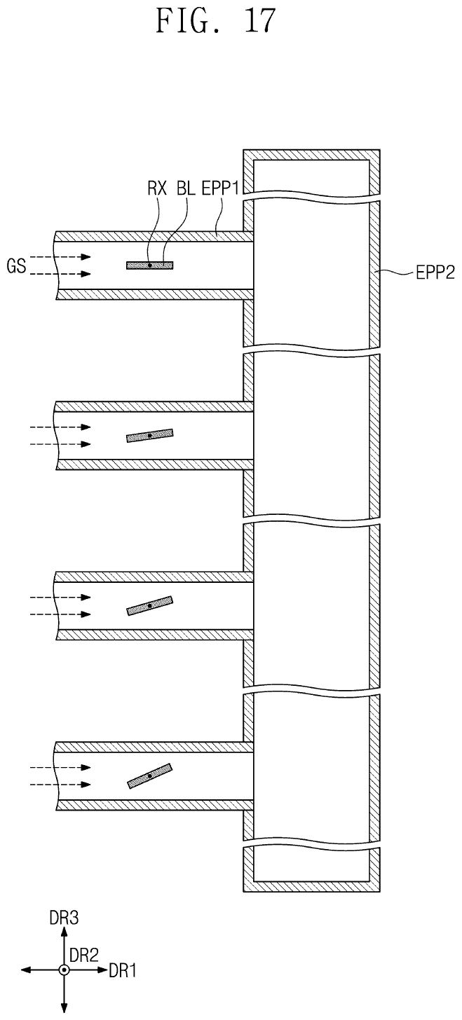

FIG. 16 is a side view of the discharge part illustrated in FIG. 1. FIG. 17 is a cross-sectional view taken along line III-III′ illustrated in FIG. 1.

For convenience of description, FIG. 17 illustrates barrier films BL, of the discharge valves EVV, disposed inside the first discharge pipes EPP1, and other configurations of the discharge valves EVV are omitted.

Referring to FIG. 16, the substrate processing apparatus SPA may include a controller (controlling circuitry) CON. The controller CON may be connected to the discharge valves EVV and the first pressure measurement portions PM1. The controller CON may control the discharge valves EVV according to pressures, in the first discharge pipes EPP1, measured by the first pressure measurement portions PM1. The discharge valves EVV may be controlled by the controller CON to control open ratios of passages defined inside the first discharge pipes EPP1.

Referring to FIGS. 16 and 17, the discharge valves EVV may respectively include the barrier films BL disposed inside the first discharge pipes EPP1. The barrier films BL may rotate with respect to rotation axes RX parallel to the second direction DR2. Operations of the barrier films BL may be controlled by the controller CON. The passages defined inside the first discharge pipes EPP1 may be closed or opened by the barrier films BL.

The controller CON may receive information about the pressures, in the first discharge pipes EPP1, measured by the first pressure measurement portions PM1. The controller CON may control operations of the barrier films BL according to the pressures measured by the first pressure measurement portions PM1, such that open ratios of the passages inside the first discharge pipes EPP1 are controlled. That is, the discharge valves EVV may control open ratios of the passages inside the first discharge pipes EPP1 according to the pressures measured by the first pressure measurement portions PM1.

In an embodiment, the barrier films BL may contribute to an increase in the open ratios of the passages inside the first discharge pipes EPP1 toward the upper portion, for example. That is, the barrier films BL may allow the passages inside the first discharge pipes EPP1 to be further opened toward the upper portion.

Even though the heated gas GS is supplied to the chamber CH, the density of the gas GS at the lower portion inside the chamber CH may be greater than the density of the gas GS at the upper portion of the chamber CH. In an embodiment, the density of the gas GS inside the chamber CH may gradually increase from the upper portion toward the lower portion, for example.

When the discharge valves EVV are not used, an amount of the gas GS discharged via the first discharge pipes EPP1 may gradually increase from the upper portion toward the lower portion. Accordingly, pressures, generated by the gas GS, in the first discharge pipes EPP1 may gradually increase from the upper portion toward the lower portion. That is, the gas GS may not be uniformly discharged in the first discharge pipes EPP1.

When a discharge operation is initially performed, all the barrier films BL may be horizontally disposed in the same direction. That is, the open ratios of the first discharge pipes EPP1 may be set to be maximum.

An amount of the gas GS supplied to the first discharge pipes EPP1 may gradually increase from the upper portion toward the lower portion. Accordingly, the pressures, in the first discharge pipes EPP1, measured by the first pressure measurement portions PM1 may gradually increase from the upper portion toward the lower portion. As the pressure in the first discharge pipe EPP1 increases, the controller CON may decrease the open ratio of the passage of the first discharge pipe EPP1 by further widely rotating the barrier film BL.

Since an amount of the gas GS supplied to the first discharge pipes EPP1 gradually increases from the upper portion toward the lower portion, the barrier films BL may allow the open ratios of the passages inside the first discharge pipes EPP1 to increase from the lower portion toward the upper portion. In an embodiment, the barrier films BL may rotate such that an angle defined by the barrier films BL and the first direction DR1 gradually increases from the lower portion toward the upper portion, for example.

An open ratio of the first discharge pipe EPP1 supplied with a relatively large amount of the gas GS may decrease, and an open ratio of the first discharge pipe EPP1 supplied with a relatively small amount of the gas GS may increase. Accordingly, an amount of the gas GS discharged via the first discharge pipes EPP1 may be equalized. As a result, the pressures in the first discharge pipes EPP1 are equalized, and pressures, in the first discharge pipes EPP1, measured by the first pressure measurement portions PM1 may be equalized.

Therefore, the controller CON may control the operations of the barrier films BL such that the pressures in the first discharge pipes EPP1 are equalized. In an embodiment, the controller CON may control the operations of the barrier films BL such that the pressures in the first discharge pipes EPP1 are equalized to a target pressure, for example.

When the pressure in the first discharge pipe EPP1 is smaller than a target pressure, the controller CON may rotate the barrier film BL such that an open ratio of the passage of the first discharge pipe EPP1 increases. Additionally, when the pressure in the first discharge pipe EPP1 is greater than a target pressure, the controller CON may rotate the barrier film BL such that an open ratio of the passage of the first discharge pipe EPP1 decreases.

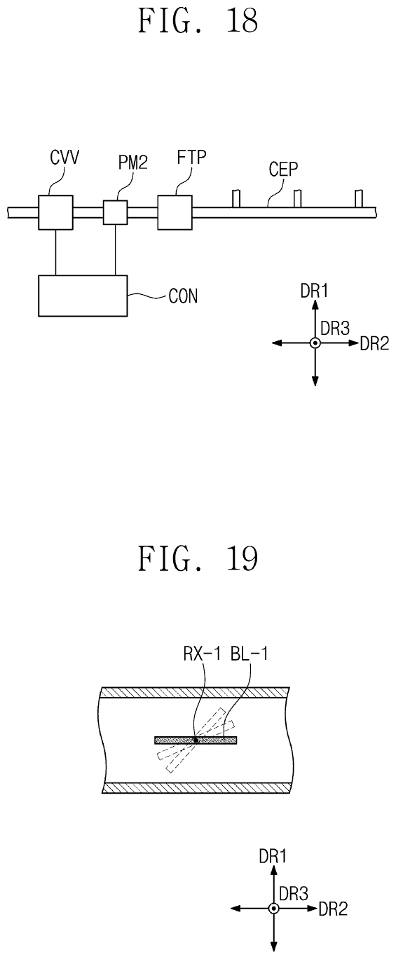

FIG. 18 is a view illustrating the common discharge pipe, the fume trap, the second pressure measurement portion, and the common discharge valve which are illustrated in FIG. 1. FIG. 19 is a view illustrating a barrier film of the common discharge valve disposed inside the common discharge pipe illustrated in FIG. 18.

Referring to FIG. 18, a fume trap FTP (or a fume collector) may be connected to a common discharge pipe CEP, and suction, collect, and remove fumes flowing into via the common discharge pipe CEP. Although not illustrated, the fume trap FTP may include a filter for filtering the fumes, or the like.

When the fumes are continuously provided to a common discharge valve CVV, the common discharge valve CVV may be contaminated to improperly operate. The fume trap FTP may remove the fumes flowing into via the common discharge pipe CEP, thereby preventing contamination of the common discharge valve CVV.

A second pressure measurement portion PM2 may measure a pressure of an air flow via a passage defined inside the common discharge pipe CEP. In an embodiment, the second pressure measurement portion PM2 may include a differential pressure gauge, for example.

The common discharge valve CVV may close or open the passage defined inside the common discharge pipe CEP. The common discharge valve CVV may control an open ratio of the passage defined inside the common discharge pipe CEP.

A controller CON may be connected to the second pressure measurement portion PM2 and the common discharge valve CVV. The controller CON may control the common discharge valve CVV according to a pressure measured by the second pressure measurement portion PM2.

The pressure in the common discharge pipe CEP should remain constant so as to ensure the consistent discharge operation. The common discharge valve CVV may control the open ratio of the passage inside the common discharge pipe CEP according to the pressure, in the common discharge pipe CEP, measured by the second pressure measurement portion PM2.

Referring to FIGS. 18 and 19, the common discharge valve CVV may include a barrier film BL-1 disposed inside the common discharge pipe CEP. A shape of the barrier film BL-1 is illustrated, and the barrier film BL-1 may have various shapes according to configurations of valves. The barrier film BL-1 may rotate with respect to a rotation axis RX-1 parallel to the third direction DR3.

When a pressure, in the common discharge pipe CEP, measured by the second pressure measurement portion PM2 is smaller than a target pressure, the controller CON may rotate the barrier film BL-1 such that an open ratio of the passage inside the common discharge pipe CEP increases. In this case, an air flow increases, and thus the pressure in the common discharge pipe CEP may increase.

When a pressure, in the common discharge pipe CEP, measured by the second pressure measurement portion PM2 is greater than a target pressure, the controller CON may rotate the barrier film BL-1 such that an open ratio of the passage inside the common discharge pipe CEP decreases. In this case, an air flow decreases, and thus the pressure in the common discharge pipe CEP may decrease. Therefore, the pressure in the common discharge pipe CEP may remain constant at a target pressure according to operations of the controller CON and the common discharge valve CVV.

FIG. 20 is an exploded perspective view of first and second support parts and rollers disposed below one substrate illustrated in FIG. 8.

Referring to FIG. 20, first support bars SB1 may extend in the first direction DR1, and be arranged in the second direction DR2. Support pins SPN may be disposed on the respective first support bars SB1.

Second support bars SB2 may extend in the second direction DR2, and be spaced apart from each other in the first direction DR1. The first support bars SB1 may be disposed between the second support bars SB2. The first support bars SB1 may be connected to the second support bars SB2.

Rollers ROL may be spaced apart from each other in the first direction DR1, and be arranged in the second direction DR2. The rollers ROL may rotate clockwise and counterclockwise with respect to rotation axes RX-2 parallel to the first direction DR1. The second support bars SB2 may be disposed on the rollers ROL and reciprocate in the second direction DR2 according to rotation of the rollers ROL.

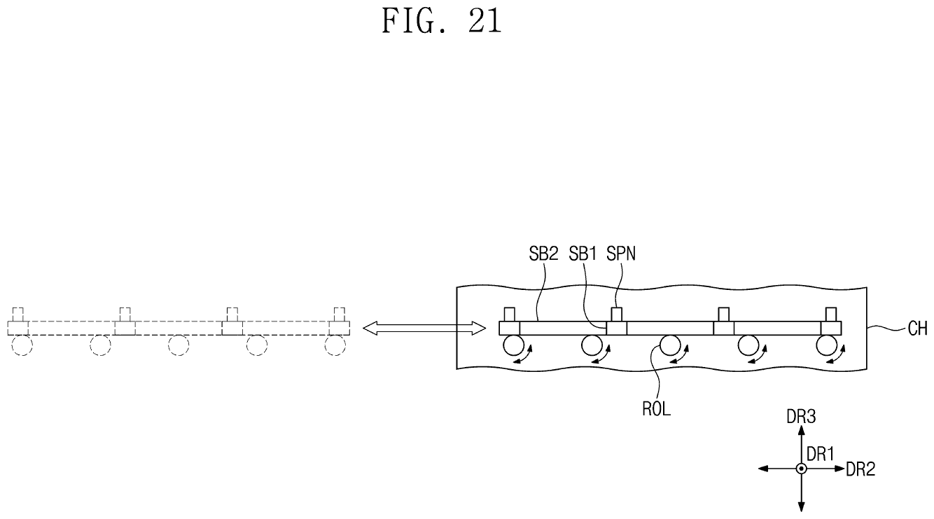

FIG. 21 is a view describing an operation of first and second support bars entering into and exiting from a chamber via rollers.

FIG. 21 illustrates a state when viewed from the inside of a chamber toward the first direction DR1, and a part of an inner side surface of a chamber CH when viewed from the first direction DR1.

Referring to FIG. 21, a second support bar SB2 may enter into or exit outside the chamber CH via rollers ROL. First support bars SB1 and support pins SPN may also enter into or exit outside the chamber CH according to movement of the second support bar SB2.

The rollers ROL may allow the first and second support bars SB1 and SB2 to be easily separated from the chamber CH. Although not illustrated, one side wall of both side walls, of the chamber CH, facing each other in the second direction DR2 may be separated from the chamber CH such that the first and second support bars SB1 and SB2 exit from the chamber CH.

When the substrate processing process is performed multiple times, it may be desired for the first and second support bars SB1 and SB2 to be cleaned. In an embodiment of the inventive concept, the first and second support bars SB1 and SB2 are easily separated from the chamber CH, and a cleaning process of the first and second support bars SB1 and SB2 may be performed.

In an embodiment of the inventive concept, fumes, which may be injected via an external air supply pipe, are blocked by a mesh filter, and are evenly discharged via discharge pipes, thereby making it possible to prevent contamination of a substrate.

In the above, description has been made with reference to preferred embodiments of the inventive concept, but those skilled in the art or those of ordinary skill in the relevant technical field may understand that various modifications and changes may be made to the inventive concept within the scope not departing from the spirit and the technical scope of the inventive concept described in the claims to be described later. In addition, the embodiments disclosed in the inventive concept are not intended to limit the technical spirit of the inventive concept, and all technical ideas within the scope of the following claims and their equivalents should be construed as being included in the scope of the inventive concept.

What is claimed is:

1. A substrate processing apparatus comprising:
a chamber in which a substrate is disposed;
an external air supply pipe connected to a first side of the chamber and extending into the chamber;
a gas supply pipe disposed inside the external air supply pipe;
a mesh filter disposed inside the external air supply pipe and between an end of the gas supply pipe and an end of the external air supply pipe; and
a plurality of first discharge pipes connected to a second side of the chamber which is opposite to the first side and extending into the chamber.

2. The substrate processing apparatus of claim 1, wherein the mesh filter is detachably coupled to the external air supply pipe.

3. The substrate processing apparatus of claim 2, wherein the mesh filter is detachably coupled to the external air supply pipe through an opening defined in the external air supply pipe.

4. The substrate processing apparatus of claim 1, wherein the end of the gas supply pipe and the mesh filter are disposed outside the chamber.

5. The substrate processing apparatus of claim 1, wherein the end of the gas supply pipe and the mesh filter are disposed inside the chamber.

6. The substrate processing apparatus of claim 1, wherein the external air supply pipe comprises a transparent material.

7. The substrate processing apparatus of claim 1, wherein a gas is injected into the chamber via the gas supply pipe,
external air is supplied into the chamber via the external air supply pipe after an injection of the gas is stopped, and
the gas and the external air are discharged via the plurality of first discharge pipes.

8. The substrate processing apparatus of claim 1, further comprising a plurality of discharge valves, outside the chamber, respectively connected to the plurality of first discharge pipes.

9. The substrate processing apparatus of claim 8, wherein the plurality of discharge valves controls open ratios of passages inside the plurality of first discharge pipes, and the open ratios of the passages of the plurality of first discharge pipes gradually increase toward an upper portion.

10. The substrate processing apparatus of claim 9, further comprising a plurality of first pressure measurement portions which are disposed between the chamber and the plurality of discharge valves, respectively connected to the plurality of first discharge pipes, and measure pressures in the plurality of first discharge pipes.

11. The substrate processing apparatus of claim 10, wherein the open ratios of the passages of the plurality of first discharge pipes are controlled by the plurality of discharge valves according to pressures measured by the plurality of first pressure measurement portions.

12. The substrate processing apparatus of claim 1, further comprising:
a second discharge pipe connected to the plurality of first discharge pipes;
a common discharge pipe connected to the second discharge pipe;
a common discharge valve connected to the common discharge pipe; and
a second pressure measurement portion connected to the common discharge pipe and disposed more next to the second discharge pipe than the common discharge valve.

13. The substrate processing apparatus of claim 12, wherein an open ratio of a passage inside the common discharge pipe is controlled by the common discharge valve according to a pressure, in the common discharge pipe, measured by the second pressure measurement portion.

14. The substrate processing apparatus of claim 12, further comprising a fume trap connected to the common discharge pipe and disposed more next to the second discharge pipe than the second pressure measurement portion.

15. The substrate processing apparatus of claim 1, further comprising:
a plurality of rollers connected to an inner side surface of the chamber;
a plurality of support bars connected to each other, disposed on the plurality of rollers, and including heating wires; and
a plurality of support pins disposed on the plurality of support bars,
wherein the substrate is disposed on the plurality of support pins.

16. The substrate processing apparatus of claim 15, wherein the plurality of support bars moves along the plurality of rollers, and enters into and exit from the chamber.

17. The substrate processing apparatus of claim 1, further comprising a heater connected to the gas supply pipe.

18. A substrate processing apparatus comprising:
a chamber in which a substrate is disposed;
an external air supply pipe connected to a first side of the chamber and extending into the chamber;
a gas supply pipe disposed inside the external air supply pipe;
a plurality of first discharge pipes connected to a second side of the chamber which is opposite to the first side and extending into the chamber; and
a plurality of discharge valves, outside the chamber, respectively connected to the plurality of first discharge pipes,
wherein the plurality of discharge valves controls open ratios of passages inside the plurality of first discharge pipes, and the open ratios of the passages of the plurality of first discharge pipes gradually increase toward an upper portion.

19. The substrate processing apparatus of claim 18, further comprising a mesh filter disposed inside the external air supply pipe and between an end of the gas supply pipe and an end of the external air supply pipe,
wherein the mesh filter is detachably coupled to the external air supply pipe.

20. The substrate processing apparatus of claim 18, further comprising:
a second discharge pipe connected to the plurality of first discharge pipes;
a common discharge pipe connected to the second discharge pipe;
a common discharge valve connected to the common discharge pipe; and
a fume trap connected to the common discharge pipe and disposed more next to the second discharge pipe than the common discharge valve.
